(19) United States
(12) Patent Application Publication
(10) Pub. No.: US 2015/0042414 A1
(43) Pub. Date: Feb. 12, 2015

(54) COMPOSITE ELECTRONIC COMPONENT

(71) Applicant: SAMSUNG ELECTRO-MECHANICS CO., LTD., Suwon-Si (KR)

(72) Inventors: Young Ghyu AHN, Suwon-Si (KR); Sang Soo PARK, Suwon-Si (KR); Min Cheol PARK, Suwon-Si (KR); Byoung Hwa LEE, Suwon-si (KR)

(21) Appl. No.: 14/454,628

(22) Filed: Aug. 7, 2014

(30) Foreign Application Priority Data
Aug. 9, 2013 (KR) 10-2013-0094834

(51) Int. Cl. H03H 7/01

(52) U.S. Cl. CPC H03H 7/0115; H03H 7/0138
USPC 333/184

(57) ABSTRACT

A composite electronic component may include: an input terminal part receiving power converted by a power managing part; a power stabilizing part stabilizing the power and including a composite body including a capacitor and a toroidal coil and having a hexahedral shape, the capacitor including a plurality of dielectric layers, internal electrodes disposed to face each other with the respective dielectric layers interposed therebetween, and capacitor electrodes electrically coupled to the internal electrodes, and the toroidal coil being wound around the capacitor, and the capacitor and the toroidal coil being embedded in a magnetic material of the composite body; and an output terminal part supplying the stabilized power.

### CROSS-REFERENCE TO RELATED APPLICATION

This application claims the benefit of Korean Patent Application No. 10-2013-0094834 filed on Aug. 9, 2013, with the Korean Intellectual Property Office, the disclosure of which is incorporated herein by reference.

### BACKGROUND

The present disclosure relates a composite electronic component including a plurality of passive devices.

In accordance with the recent trend toward compactness and slimness of electronic devices and multifunctionalization in the electronic devices, demands have been made for the electronic devices to be miniaturized and multi-functionalized.

The electronic devices as described above may include a power semiconductor based power management integrated circuit (PMIC) serving to efficiently control and manage a limited battery resource in order to satisfy the various service requirements.

However, as electronic devices have multifunctionalized, the number of direct current (DC)/DC converters included in the PMIC has increased, and the number of passive elements that should be included in a power input terminal and a power output terminal of the PMIC has also increased.

In this case, an area of the electronic device in which components are disposed may be inevitably increased, which may limit miniaturization of the electronic device.

In addition, significant noise may be generated due to wiring patterns of the PMIC and peripheral circuits of the PMIC.

### RELATED ART DOCUMENT

(Patent Document 1) Korean Patent Laid-Open Publication No. 2003-0014586

### SUMMARY

An exemplary embodiment in the present disclosure may provide a composite electronic component capable of being mounted in a decreased area in a driving power supplying system.

An exemplary embodiment in the present disclosure may also provide a composite electronic component capable of suppressing the occurrence of noise in a driving power supplying system.

According to an exemplary embodiment in the present disclosure, a composite electronic component may include: an input terminal part receiving power converted by a power managing part; a power stabilizing part stabilizing the power; and an output terminal part supplying the stabilized power, wherein the power stabilizing part includes: a toroidal coil having an air-core part formed therein; and a capacitor disposed in the air-core part.

The toroidal coil may be wound to encompass a first main surface, a first end surface, a second main surface, and a second end surface of the capacitor.

The toroidal coil may be wound to encompass a first main surface, an upper surface, a second main surface, and a lower surface of the capacitor.

The toroidal coil may be extended on a plane defined by a length direction and a width direction of the composite electronic component.

The toroidal coil may be extended on a plane defined by a thickness direction and a width direction of the composite electronic component.

A winding center of the toroidal coil may be formed on a plane defined by a length direction and a width direction of the composite electronic component.

The toroidal coil may be electrically connected to the input terminal part and the output terminal part.

The capacitor may include: a plurality of dielectric layers; a plurality of internal electrodes disposed to face each other with the respective dielectric layers interposed therebetween; and a plurality of capacitor electrodes electrically connected to the internal electrodes.

The power stabilizing part may decrease noise of the power.

The toroidal coil and the capacitor may be insulated from each other.

The composite electronic component may further include a printed circuit board (PCB) including an input pattern, a ground pattern, and an output pattern, wherein the input terminal part is connected to the input pattern, one of the plurality of capacitor electrodes is connected to the ground pattern, and the output terminal part is connected to the output pattern.

According to an exemplary embodiment in the present disclosure, a composite electronic component may include: a composite element including an input terminal part receiving power converted by a power managing part, a power stabilizing part stabilizing the power and including a toroidal coil having an air-core part formed therein and a capacitor disposed in the air-core part and insulated from the toroidal coil, and an output terminal part supplying the stabilized power; and a printed circuit board (PCB) including an input pattern, a ground pattern, and an output pattern, wherein the capacitor includes a plurality of dielectric layers, a plurality of internal electrodes disposed to face each other with the respective dielectric layers interposed therebetween, and a plurality of capacitor electrodes electrically connected to the internal electrodes, and wherein the input terminal part is connected to the input pattern, one of the plurality of capacitor electrodes is connected to the ground pattern, and the output terminal part is connected to the output pattern.

According to an exemplary embodiment in disclosure, a composite electronic component may include: a composite body including a capacitor and a toroidal coil and having a hexahedral shape, the capacitor including a plurality of dielectric layers, internal electrodes disposed to face each other with the respective dielectric layers interposed therebetween, and capacitor electrodes electrically coupled to the internal electrodes, and the toroidal coil being wound around the capacitor, and the capacitor and the toroidal coil being embedded in a magnetic material; an input terminal part formed on a second main surface of the composite body and connected to one end of the toroidal coil; and an output terminal part formed on a first main surface of the composite body and connected to the other end of the toroidal coil.

The capacitor electrodes may protrude from at least one of upper and lower surfaces of the composite body having the hexahedral shape.

According to an exemplary embodiment in the present disclosure, a composite electronic component may include: an input terminal part receiving power converted by a power managing part; a power stabilizing part stabilizing the power and including a composite body including a capacitor and a toroidal coil and having a hexahedral shape, the capacitor including a plurality of dielectric layers, internal electrodes disposed to face each other with the respective dielectric layers interposed therebetween, and capacitor electrodes electrically coupled to the internal electrodes, and the toroidal coil being wound around the capacitor, and the capacitor and the toroidal coil being embedded in a magnetic material; and an output terminal part supplying the stabilized power.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a view showing a driving power supplying system supplying driving power to a predetermined terminal requiring the driving power through a battery and a power managing part;

FIG. 2 is a view showing a layout in which the driving power supplying system is disposed;

FIG. 3 is a circuit diagram of a composite electronic component according to an exemplary embodiment in the present disclosure;

FIG. 4 is a view showing a layout in which a driving power supplying system using the composite electronic component according to an exemplary embodiment in the present disclosure is disposed;

FIG. 5 is a perspective view schematically showing the composite electronic component according to an exemplary embodiment in the present disclosure;

FIG. 6 is a cross-sectional view of the composite electronic component of FIG. 5;

FIG. 7 is a schematic perspective view showing a multilayer ceramic capacitor according to an exemplary embodiment in the present disclosure;

FIG. 8 is a schematic cross-sectional view of the multilayer ceramic capacitor taken along line C-C′ of FIG. 7;

FIG. 9 is a view showing internal patterns of the multilayer ceramic capacitor according to an exemplary embodiment in the present disclosure;

FIG. 10 is a bottom view of the composite electronic component shown in FIG. 5;

FIG. 11 is a view showing a land pattern in which the composite electronic component according to an exemplary embodiment in the present disclosure is mounted;

FIG. 12 is a perspective view schematically showing a composite electronic component according to another exemplary embodiment in the present disclosure;

FIGS. 13A and 13B are cross-sectional views of the composite electronic component of FIG. 12; and

FIG. 14 is a view showing a land pattern in which the composite electronic component according to another exemplary embodiment in the present disclosure is mounted.

### DETAILED DESCRIPTION

Exemplary embodiments in the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

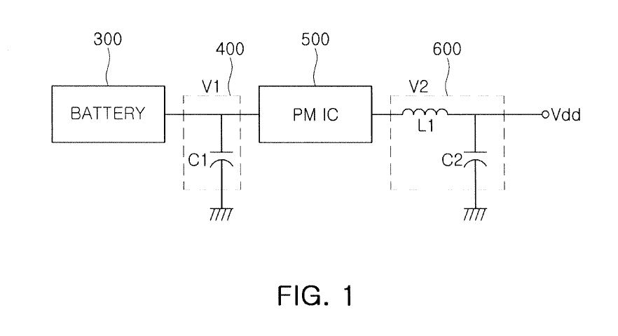

FIG. 1 is a view showing a driving power supplying system supplying driving power to a predetermined terminal requiring the driving power through a battery and a power managing part.

Referring to FIG. 1, the driving power supplying system may include a battery 300, a first power stabilizing part 400, a power managing part 500, and a second power stabilizing part 600.

The battery 300 may supply power to the power managing part 500. Here, the power supplied to the power managing part 500 by the battery 300 will be defined as first power.

The first power stabilizing part 400 may stabilize first power V₁ and supply the stabilized first power to the power managing part. In detail, the first power stabilizing part 400 may include a capacitor C₁, formed between a connection terminal between the battery 300 and the power managing part 500 and a ground. The capacitor C₁ may decrease noise included in the first power.

In addition, the capacitor C₁ may be charged with electric charges. In addition, in the case in which the power managing part 500 instantaneously consumes a large amount of current, the capacitor C₁ may discharge the electric charges charged therein, thereby suppressing a voltage variation in the power managing part 500.

The capacitor C₁ may be a high capacitance capacitor.

The power managing part 500 may serve to convert power input to an electronic apparatus into power appropriate for the electronic apparatus and distribute, charge, and control the power. Therefore, the power managing part 500 may generally include a direct current (DC) to DC converter.

In addition, the power managing part 500 may be implemented by a power management integrated circuit (PMIC).

The power managing part 500 may convert the first power V₁ into second power V₂. The second power V₂ may be required by a predetermined device connected to an output terminal of the power managing part 500 to receive driving power from the power managing part 500.

The second power stabilizing part 600 may stabilize the second power V₂ and transfer the stabilized second power to an output terminal V_{dd}. The predetermined device receiving the driving power from the power managing part 500 may be connected to the output terminal V_{dd}.

In detail, the second power stabilizing part 600 may include an inductor L₁ connected in series with the power managing part 500 and the output terminal V_{dd} between the power managing part 500 and the output terminal V_{dd}. In addition, the second power stabilizing part 600 may include a capacitor C₂ formed between a connection terminal between the power managing part 500 and the output terminal V_{dd} and a ground.

The second power stabilizing part 600 may decrease noise included in the second power V₂.

In addition, the second power stabilizing part 600 may stably supply the power to the output terminal V_{dd}.

The inductor L₁ may be a power inductor that may be applied to a large amount of current.

In addition, the capacitor C₂ may be a high capacitance capacitor.

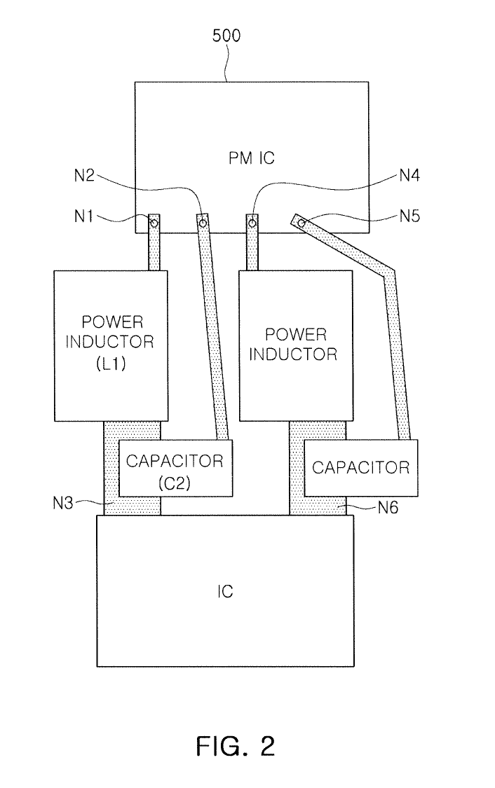

FIG. 2 is a view showing a layout in which the driving power supplying system is disposed.

Referring to FIG. 2, a layout in which the power managing part 500, the power inductor L₁, and the second capacitor C₂ are disposed may be confirmed.

Generally, the power managing part PMIC 500 may include several to several ten DC to DC converters. In addition, in order to implement a function of the DC to DC converter, each of the DC to DC converters may require a power inductor and a high capacitance capacitor.

Referring to FIG. 2, the power managing part 500 may have predetermined terminals N1 and N2. The power managing part 500 may receive power from the battery and convert the power using the DC to DC converter. In addition, the power managing part 500 may supply the converted power through the first terminal N1. The second terminal N2 may be a ground terminal.

Here, the first power inductor L₁ and the second capacitor C₂ may receive power from the first terminal N1, stabilize the power, and supply driving power through a third terminal N3. Therefore, the first power inductor L₁ and the second capacitor C₂ may serve as the second power stabilizing part.

Since fourth to sixth terminals N4 to N6 shown in FIG. 2 perform the same functions as those of the first to third terminals N1 to N3, a detailed description thereof will be omitted.

The important fact in designing the layout of the driving power supplying system is that the power managing unit, the power inductor, and the high capacitance capacitor need to be positioned as closely as possible to one another. In addition, designing a short and thick wiring of a power line may be required.

The reason for this is that when the requirements described above are satisfied, an area required for the disposition of a component may be decreased and the occurrence of noise may be suppressed.

In a case in which the number of output terminals of the power managing unit 500 is small, disposing the power inductor and the high capacitance capacitor to be close to each other may be facilitated. However, in a case in which various output terminals of the power managing unit 500 need to be used, the power inductor and the high capacitance capacitor may not be normally disposed due to an increase in density of the component. In addition, a situation in which the power inductor and the high capacitance capacitor need to be disposed in a non-optimal state depending on a priority of power may occur.

For example, since sizes of the power inductor and the high capacitance capacitor are large, a situation in which lengths of a power line and a signal line are inevitably increased at the time of actually disposing the power inductor and the high capacitance capacitor may occur.

In a case in which the power inductor and the high capacitance capacitor are disposed in a non-optimal state, an interval between the power inductor and the high capacitance capacitor and the length of the power line may be increased, such that noise may occur. The noise may have a negative effect on the driving power supplying system.

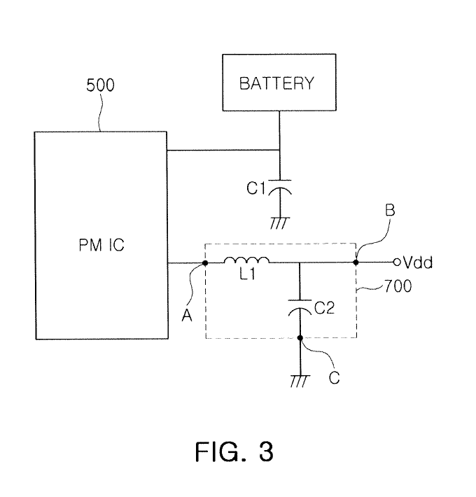

FIG. 3 is a circuit diagram of a composite electronic component according to an exemplary embodiment in the present disclosure.

Referring to FIG. 3, a composite electronic component 700 may include an input terminal part A (input terminal), a power stabilizing part, an output terminal part B (output terminal), and a ground terminal part C (ground terminal).

The power stabilizing part may include the power inductor L₁ and the second capacitor C₂.

The composite electronic component 700 may perform functions of the second power stabilizing part described above.

The input terminal part A may receive power converted by the power managing part 500.

The power stabilizing part may stabilize the power supplied from the input terminal part A.

The output terminal part B may supply the stabilized power to the output terminal V_{dd}.

The ground terminal part C may connect the power stabilizing part to a ground.

Meanwhile, the power stabilizing part may include the power inductor L₁ connected between the input terminal part A and the output terminal part B and the second capacitor C₂ connected between the ground terminal part C and the output terminal part.

Referring to FIG. 3, the power inductor L₁ and the second capacitor C₂ share the output terminal part B with each other, whereby an interval between the power inductor L₁ and the second capacitor O₂ may be decreased.

As described above, the composite electronic component 700 may be formed by implementing the power inductor and the high capacitance capacitor provided in an output power terminal of the power managing part 500 as a single component. Therefore, in the composite electronic component 700, a degree of integration of elements may be improved.

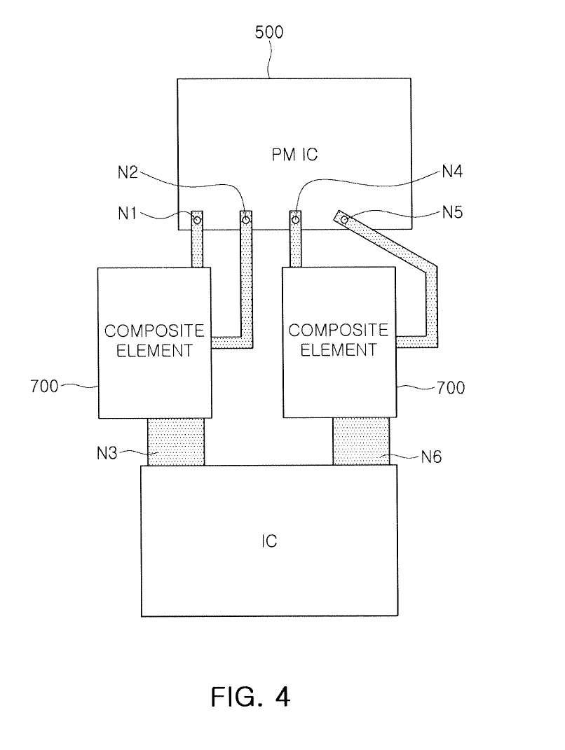

FIG. 4 is a view showing a layout in which a driving power supplying system using the composite electronic component according to an exemplary embodiment in the present disclosure is disposed.

Referring to FIG. 4, it may be confirmed that the second capacitor C₂ and the power inductor L₁ shown in FIG. 2 are replaced by the composite electronic component according to an exemplary embodiment in the present disclosure.

As described above, the composite electronic component may serve as the second power stabilizing part.

In addition, a wiring length may be significantly decreased by replacing the second capacitor C₂ and the power inductor L₁ with the composite electronic component according to an exemplary embodiment in the present disclosure. Further, the number of disposed elements is decreased, whereby the elements may be optimally disposed.

That is, according to the exemplary embodiment in the present disclosure, the power managing unit, the power inductor, and the high capacitance capacitor may be positioned as closely as possible to one another, and a short and thick wiring of the power line may be designed.

Meanwhile, electronic apparatus manufacturers have made an effort to decrease a size of a printed circuit board (PCB) included in an electronic apparatus in order to satisfy consumers' demand. Therefore, it has been demanded to increase a degree of integration of an IC mounted on the PCB. As in the composite electronic component according to an exemplary embodiment in the present disclosure, a plurality of devices are implemented as a single composite component, whereby such a demand may be satisfied.

Further, according to an exemplary embodiment in the present disclosure, two components (second capacitor and power inductor) are implemented as a single composite electronic component, whereby an area in which they are mounted on the PCB may be decreased. According to an exemplary embodiment in the present disclosure, an mounting area may be decreased as compared with an existing disposition layout by about 10 to 30%.

Further, according to an exemplary embodiment in the present disclosure, the power managing unit 500 may supply the driving power to the IC through the shortest wiring.

Composite Electronic Component

Hereinafter, exemplary embodiments in the present disclosure will be described in detail with reference to the accompanying drawings.

A direction of a hexahedron will be defined in order to clearly describe exemplary embodiments in the present disclosure. L, W and T shown in the accompanying drawings refer to a length direction, a width direction, and a thickness direction, respectively.

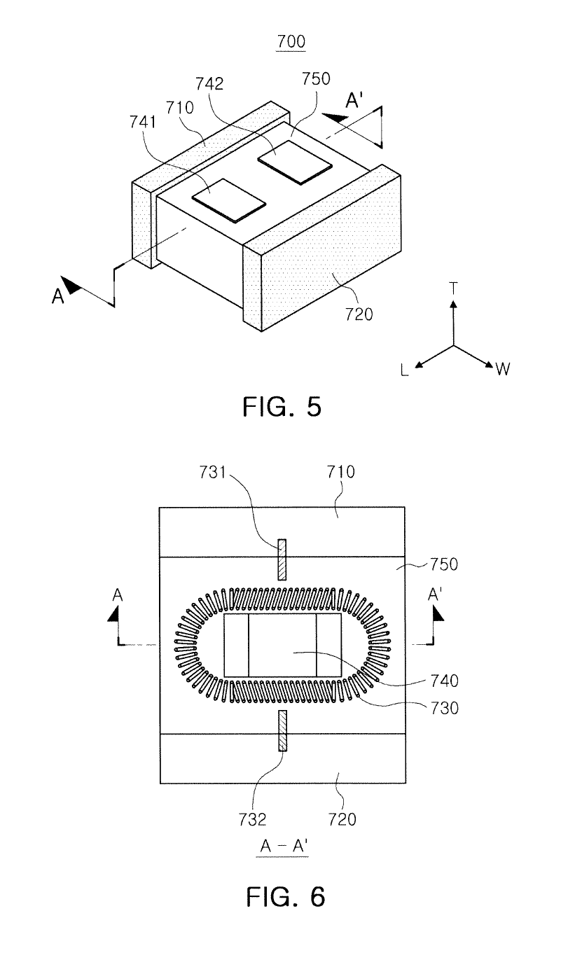

FIG. 5 is a perspective view schematically showing the composite electronic component according to an exemplary embodiment in the present disclosure.

FIG. 6 is a cross-sectional view of the composite electronic component of FIG. 5.

Referring to FIGS. 5 and 6, the composite electronic component 700 according to an exemplary embodiment in the present disclosure may include a composite body including a capacitor 740 and a toroidal coil 730 and having a hexahedral shape, the capacitor 740 including a plurality of dielectric layers, internal electrodes disposed to face each other with the respective dielectric layers interposed therebetween, and capacitor electrodes electrically coupled to the internal electrodes, and the toroidal coil 730 being wound around the capacitor and being embedded in a magnetic material 750.

The composite body may be used as a power stabilizing part.

In detail, the composite electronic component 700 may include the toroidal coil 730 having an air-core part formed therein and the capacitor 740 disposed in the air-core part. Here, the air-core part may refer to a magnetic region formed between the center of the composite body and the toroidal coil 730.

Meanwhile, the toroidal coil 730 and the capacitor 740 may be insulated from each other within the composite electronic component 700.

According to the exemplary embodiment, the capacitor 740 may not be affected by a magnetic flux generated by the toroidal coil 730.

In addition, the composite electronic component 700 according to an exemplary embodiment in the present disclosure may include an input terminal part 710 formed on a second main surface of the composite body and connected to one end of the toroidal coil 730. The input terminal part 710 may receive the power converted by the power managing part.

In addition, the composite electronic component 700 according to an exemplary embodiment in the present disclosure may include an output terminal part 720 formed on a first main surface of the composite body and connected to the other end of the toroidal coil 730. The output terminal part 720 may supply stabilized power.

In the exemplary embodiment, the composite body having the hexahedral shape may have first and second main surfaces opposing each other and first and second side surfaces and upper and lower surfaces connecting the first and second main surfaces to each other.

For convenience of explanation, main surfaces refer to surfaces formed in parallel with a plane defined by the length direction and the thickness direction, side surfaces refer to surfaces formed in parallel with a plane defined by the thickness direction and the width direction, and an upper surface or a lower surface refers to a surface formed in parallel with a plane defined by the length direction and the width direction.

In addition, for convenience of explanation, the second main surface refers to a surface on which the input terminal part 710 is formed in FIG. 5, and the first main surface refers to a surface on which the output terminal part 720 is formed in FIG. 5. Further, a first side surface refers to a side surface viewed in FIG. 5, and a second side surface refers to a side surface opposing the first side surface.

Meanwhile, a shape of the composite body is not particularly limited, but may be the hexahedral shape as shown. The composite body having the hexahedral shape may include the capacitor 740 and the toroidal coil 730 embedded in the magnetic material 750, and a method of forming the composite body is not particularly limited.

Hereinafter, the capacitor 740 configuring the composite body will be described in detail.

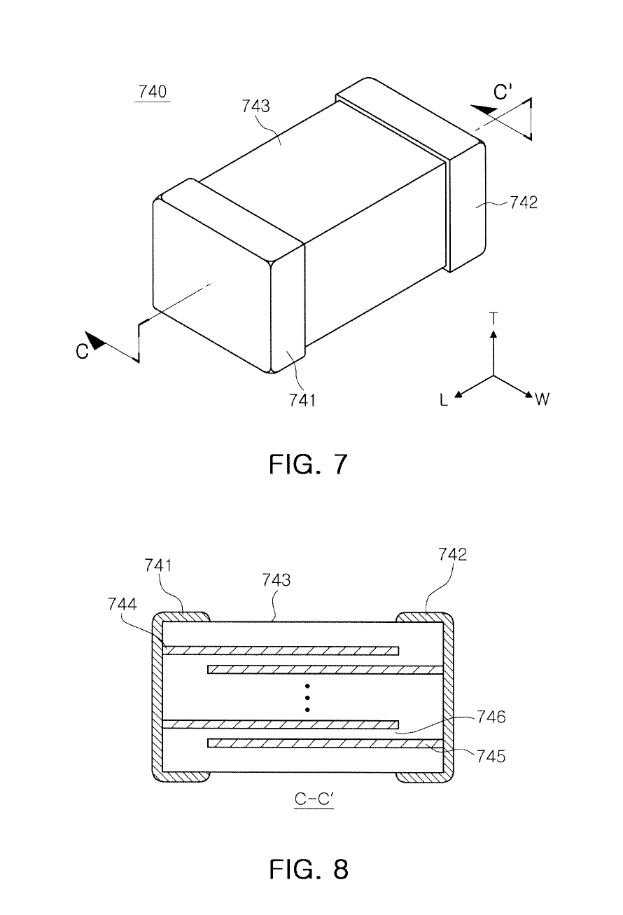

FIG. 7 is a schematic perspective view showing a multilayer ceramic capacitor according to an exemplary embodiment in the present disclosure.

FIG. 8 is a schematic cross-sectional view of the multilayer ceramic capacitor taken along line C-C′ of FIG. 7.

Referring to FIGS. 7 and 8, the multilayer ceramic capacitor according to the exemplary embodiment may include a ceramic body 743 having a plurality of dielectric layers stacked therein, a plurality of internal electrodes 744 and 745 formed on the dielectric layers, and capacitor electrodes 741 and 742 formed on end surfaces of the ceramic body 743.

A shape of the ceramic body 743 is not particularly limited, but may be generally a rectangular parallelepiped shape.

The ceramic body 743 may be formed by stacking the plurality of dielectric layers. The plurality of dielectric layers forming the ceramic body 743 may be in a sintered state, and adjacent dielectric layers may be integrated with each other so that boundaries therebetween are not readily apparent.

A single dielectric layer may be formed by sintering a ceramic green sheet containing a ceramic powder.

The ceramic powder is not particularly limited, and any ceramic power may be used as long as it is generally used in the related art. The ceramic powder may include, for example, a BaTiO₃ based ceramic powder, but is not limited thereto. An example of the BaTiO₃ based ceramic powder may include (Ba₁₋ₓCaₓ) TiO₃, Ba(Ti_{1-y}Ca_{y})O₃, (Ba₁₋ₓCaₓ) (Ti_{1-y}Zr_{y})O₃, Ba(Ti_{1-y}Zr_{y})O₃, or the like, in which Ca, Zr or the like, is partially dissolved in BaTiO₃, but is not limited thereto.

In addition, the ceramic green sheet may contain a transition metal oxide or carbide, rare earth elements, magnesium (Mg), aluminum (Al), or the like, together with the ceramic powder.

A thickness of each dielectric layer may be appropriately changed in accordance with a capacitance design of the multilayer ceramic capacitor.

The ceramic body 743 may have the plurality of internal electrodes 744 and 745 formed therein. The internal electrodes 744 and 745 may be formed on the respective dielectric layers and may be formed in the ceramic body 743 with the respective dielectric layers interposed therebetween through a sintering process.

The internal electrodes may be pairs of first and second internal electrodes 744 and 745 having different polarities and may be disposed to face each other in a stacking direction of the dielectric layers. End portions of the first and second internal electrodes 744 and 745 may be alternately exposed to both surfaces of the ceramic body 743 opposing each other.

Thicknesses of the internal electrodes 744 and 745 may be appropriately determined depending on an intended use thereof, or the like.

The capacitor electrodes 741 and 742 may be formed on the end surfaces of the ceramic body 743 and be electrically connected to the internal electrodes 744 and 745, respectively. In more detail, the capacitor electrodes may include a first capacitor electrode 741 electrically connected to the first internal electrodes 744 exposed to one end surface of the ceramic body 743 and a second capacitor electrode 742 electrically connected to the second internal electrodes 745 exposed to the other end surface of the ceramic body 743.

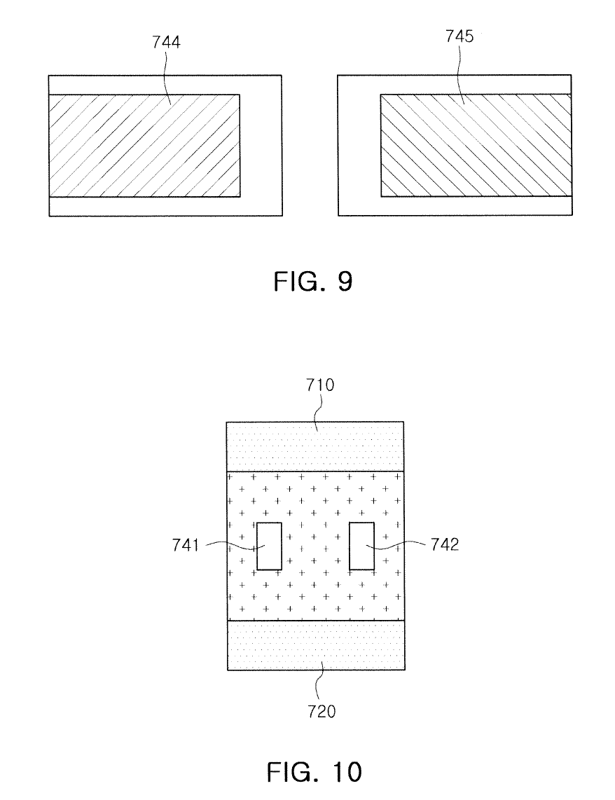

FIG. 9 is a view showing internal patterns of the multilayer ceramic capacitor according to an exemplary embodiment in the present disclosure.

The internal patterns shown in FIG. 9 are stacked, such that the multilayer ceramic capacitor according to an exemplary embodiment in the present disclosure may be formed. In addition, forms of the internal patterns are not limited to examples shown in FIG. 9, and may be variously changed.

The capacitor may serve to control a voltage supplied from a power management integrated circuit (PMIC).

Hereinafter, the toroidal coil 730 configuring the composite body will be described in detail.

Referring to FIG. 6, the toroidal coil 730 may be wound to encompass a first main surface, a first end surface, a second main surface, and a second end surface of the capacitor.

In addition, the toroidal coil 730 may be extended on a plane defined by a length direction and a width direction of the composite electronic component.

In addition, a winding center of the toroidal coil 730 may be formed on the plane defined by the length direction and the width direction of the composite electronic component.

Meanwhile, according to an exemplary embodiment in the present disclosure, one end of the toroidal coil 730 may be electrically connected to the input terminal part 710. Here, a connecting part 731 may be used in order to electrically connect one end of the toroidal coil 730 and the input terminal part 710 to each other.

In addition, the other end of the toroidal coil 730 may be electrically connected to the output terminal part 720. Here, a connecting part 732 may be used in order to electrically connect the other end of the toroidal coil 730 and the output terminal part 720 to each other.

FIG. 10 is a bottom view of the composite electronic component shown in FIG. 5.

Referring to FIGS. 5 and 10, the capacitor electrodes 741 and 742 may protrude from both of upper and lower surfaces of a hexahedral shape.

Alternatively, the capacitor electrodes 741 and 742 may protrude from at least one of the upper and lower surfaces of the hexahedral shape.

One of the plurality of capacitor electrodes 741 and 742 may be used to be connected to a ground. Here, the remaining one of the plurality of capacitor electrodes 741 and 742 may be connected to an output pattern. Therefore, one of the capacitor electrodes may be a ground terminal part.

Meanwhile, referring to FIGS. 5 and 10, the capacitor may be disposed such that the protruded capacitor electrodes 741 and 742 may be elongated in the width direction thereof.

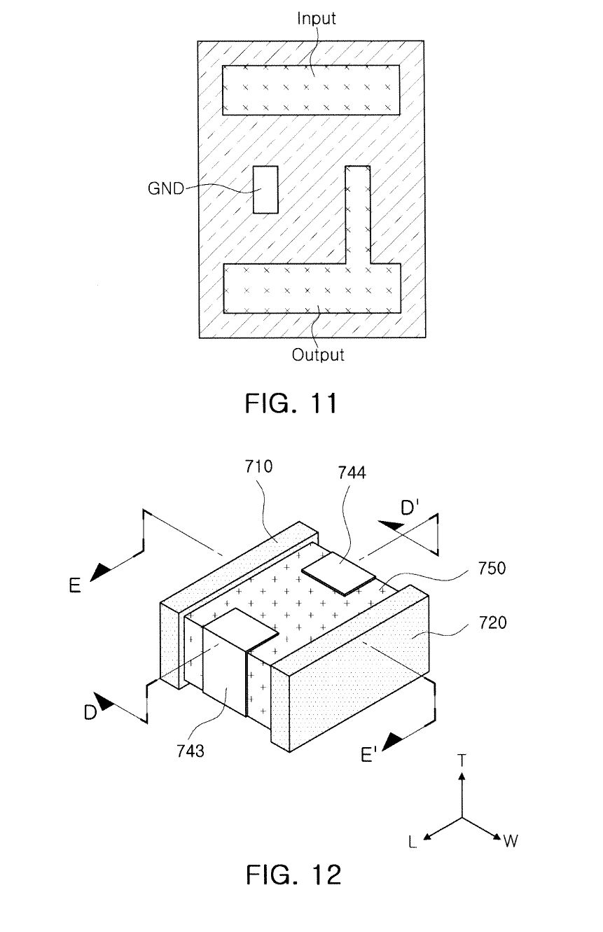

FIG. 11 is a view showing a land pattern (printed circuit board (PCB)) in which the composite electronic component according to an exemplary embodiment in the present disclosure is mounted.

That is, the composite electronic component shown in FIG. 5 may be mounted on the land pattern shown in FIG. 11.

The land pattern may include an input pattern Input, a ground pattern GND, and an output pattern Output.

Therefore, the input terminal part 710 of the composite electronic component may be connected to the input pattern Input, the ground terminal part thereof may be connected to the ground pattern GND, and the output terminal part 720 thereof may be connected to the output pattern Output.

FIG. 12 is a perspective view schematically showing a composite electronic component according to another exemplary embodiment in the present disclosure.

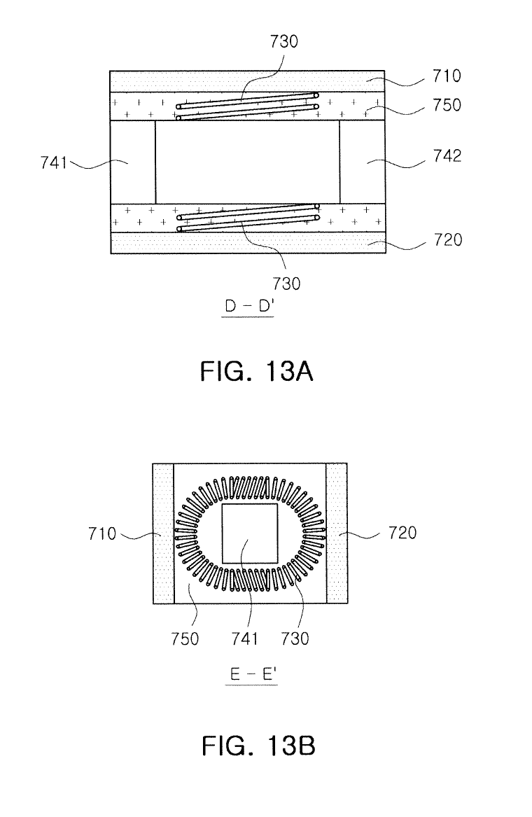

FIGS. 13A and 13B are cross-sectional views of the composite electronic component of FIG. 12.

FIG. 13A is a schematic cross-sectional view of the composite electronic component taken along line D-D′ of FIG. 12. FIG. 13B is a schematic cross-sectional view of the composite electronic component taken along line E-E′ of FIG. 12.

Referring to FIGS. 12 through 13B, the toroidal coil may be wound to encompass a first main surface, an upper surface, a second main surface, and a lower surface of the capacitor.

The toroidal coil may be extended on a plane defined by a thickness direction and a width direction of the composite electronic component.

In addition, in the composite electronic component according to another exemplary embodiment in the present disclosure, the capacitor 740 does not protrude from, and may be positioned in the magnetic material.

In order to connect the capacitor 740 and the land pattern to each other, the composite electronic component may further include connecting electrodes 743 and 744.

According to an exemplary embodiment in the present disclosure, the first capacitor electrode 741 may be connected to a first connecting electrode 743. In addition, the second capacitor electrode 742 may be connected to a second connecting electrode 744.

Here, the first connecting electrode 743 may perform the same function as that of the first capacitor electrode 741.

In a similar manner, the second connecting electrode 744 may perform the same function as that of the second capacitor electrode 742.

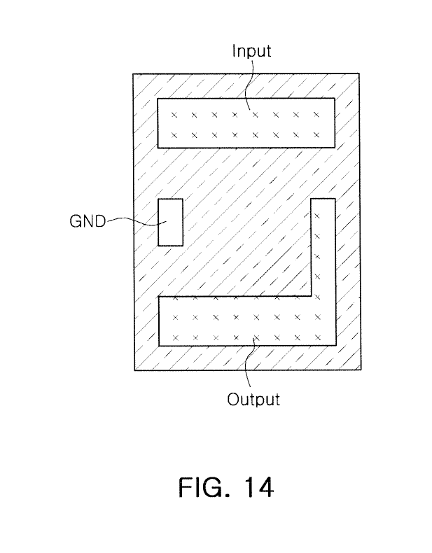

FIG. 14 is a view showing a land pattern in which the composite electronic component according to another exemplary embodiment in the present disclosure is mounted.

That is, the composite electronic component shown in FIG. 12 may be mounted on the land pattern shown in FIG. 14.

The land pattern may include an input pattern Input, a ground pattern GND, and an output pattern Output.

Therefore, the input terminal part 710 of the composite electronic component may be connected to the input pattern Input, and the output terminal part 720 thereof may be connected to the output pattern Output. In addition, the first connecting electrode 743 of the composite electronic component may be connected to the ground pattern. Further, the second connecting electrode 744 of the composite electronic component may be connected to the output pattern Output.

Since the composite electronic component according to another exemplary embodiment in the present disclosure has features that are the same as those of the composite electronic component according to an exemplary embodiment in the present disclosure described above except for a form in which the capacitor is disposed, a detailed description thereof will be omitted.

As set forth above, according to exemplary embodiments in the present disclosure, the composite electronic component capable of being mounted in a decreased area in the driving power supplying system may be provided.

In addition, according to exemplary embodiments in the present disclosure, the composite electronic component capable of suppressing generation of noise in the driving power supplying system may be provided.

While exemplary embodiments have been shown and described above, it will be apparent to those skilled in the art that modifications and variations could be made without departing from the spirit and scope in the present disclosure as defined by the appended claims.

What is claimed is:

1. A composite electronic component comprising:
an input terminal part configured to receive power converted by a power managing part;
a power stabilizing part configured to stabilize the power; and
an output terminal part configured to supply the stabilized power,
wherein the power stabilizing part includes:
a toroidal coil having an air-core part formed therein; and
a capacitor disposed in the air-core part.

2. The composite electronic component of claim 1, wherein the toroidal coil is wound to encompass a first main surface, a first end surface, a second main surface, and a second end surface of the capacitor.

3. The composite electronic component of claim 1, wherein the toroidal coil is wound to encompass a first main surface, an upper surface, a second main surface, and a lower surface of the capacitor.

4. The composite electronic component of claim 1, wherein the toroidal coil is extended on a plane defined by a length direction and a width direction of the composite electronic component.

5. The composite electronic component of claim 1, wherein the toroidal coil is extended on a plane defined by a thickness direction and a width direction of the composite electronic component.

6. The composite electronic component of claim 1, wherein a winding center of the toroidal coil is formed on a plane defined by a length direction and a width direction of the composite electronic component.

7. The composite electronic component of claim 1, wherein the toroidal coil is electrically connected to the input terminal part and the output terminal part.

8. The composite electronic component of claim 1, wherein the capacitor includes:
a plurality of dielectric layers;
a plurality of internal electrodes disposed to face each other with the respective dielectric layers interposed therebetween; and
a plurality of capacitor electrodes electrically connected to the internal electrodes.

9. The composite electronic component of claim 1, wherein the power stabilizing part decreases noise of the power.

10. The composite electronic component of claim 1, wherein the toroidal coil and the capacitor are insulated from each other.

11. The composite electronic component of claim 8, further comprising: a printed circuit board (PCB) including an input pattern, a ground pattern, and an output pattern,
wherein the input terminal part is connected to the input pattern, one of the plurality of capacitor electrodes is connected to the ground pattern, and the output terminal part is connected to the output pattern.

12. A composite electronic component comprising:
a composite element including an input terminal part configured to receive power converted by a power managing part, a power stabilizing part configured to stabilize the power and including a toroidal coil having an air-core part formed therein and a capacitor disposed in the air-core part and insulated from the toroidal coil; and an output terminal part supplying the stabilized power; and
a printed circuit board (PCB) including an input pattern, a ground pattern, and an output pattern,
wherein the capacitor includes a plurality of dielectric layers, a plurality of internal electrodes disposed to face each other with the respective dielectric layers interposed therebetween, and a plurality of capacitor electrodes electrically connected to the internal electrodes, and
wherein the input terminal part is connected to the input pattern, one of the plurality of capacitor electrodes is connected to the ground pattern, and the output terminal part is connected to the output pattern.

13. A composite electronic component comprising:
a composite body including a capacitor and a toroidal coil and having a hexahedral shape, the capacitor including a plurality of dielectric layers, internal electrodes disposed to face each other with the respective dielectric layers interposed therebetween, and capacitor electrodes electrically coupled to the internal electrodes, and the toroidal coil being wound around the capacitor, and the capacitor and the toroidal coil being embedded in a magnetic material of the composite body;
an input terminal part formed on a second main surface of the composite body and connected to one end of the toroidal coil; and
an output terminal part formed on a first main surface of the composite body and connected to the other end of the toroidal coil.

14. The composite electronic component of claim 13, wherein the capacitor electrodes protrude from at least one of upper and lower surfaces of the composite body having the hexahedral shape.

15. A composite electronic component comprising:
an input terminal part configured to receive power converted by a power managing part;
a power stabilizing part configured to stabilize the power; and
an out terminal part configured to supply the stabilized power,
wherein the power stabilizing part includes:
a composite body including a capacitor and a toroidal coil and having a hexahedral shape, the capacitor including a plurality of dielectric layers, internal electrodes disposed to face each other with the respective dielectric layers interposed therebetween, and capacitor electrodes electrically coupled to the internal electrodes, and the toroidal coil being wound around the capacitor, and the capacitor and the toroidal coil being embedded in a magnetic material of the composite body.
